(19) United States
(12) Patent Application Publication
(10) Pub. No.: US 2025/0275232 A1
(43) Pub. Date: Aug. 28, 2025

(54) SEMICONDUCTOR DEVICE

(71) Applicant: Fujian Jinhua Integrated Circuit Co., Ltd., Quanzhou City (CN)

(72) Inventors: Xiaobing Chen, Quanzhou City (CN); Chao-Lun Fu, Quanzhou City (CN)

(73) Assignee: Fujian Jinhua Integrated Circuit Co., Ltd., Quanzhou City (CN)

(21) Appl. No.: 18/747,431

(22) Filed: Jun. 18, 2024

(30) Foreign Application Priority Data
Feb. 27, 2024 (CN) 202410217201.0

(51) Int. Cl. H01L 27/06

(52) U.S. Cl. CPC H10D 84/811; H10D 1/716

(57) ABSTRACT

The present disclosure includes a substrate and a capacitor structure. The substrate includes a periphery region. The capacitor structure is disposed on the substrate and includes a plurality of capacitors arranged in an array, wherein at least two capacitors physically contact with each other along a direction being horizontal to the substrate. Through these arrangements, the semiconductor device enables to improve the possible structural defects of the semiconductor device caused by continuously increased cell-density, by arranging the dummy capacitors around the cell array, so as to obtain a more stable and more reliable structure to achieve better functions and performances.

### BACKGROUND OF THE INVENTION

### 1. Field of the Invention

The present disclosure generally relates to a semiconductor device, and more particularly, to a semiconductor device including a capacitor structure.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

An object of the present disclosure is to provide a semiconductor device where a dummy capacitor is disposed around a storage cell array, such that, the possible structural defects of the semiconductor device caused by continuously increased cell-density will be improved. In this way, the semiconductor device may therefore obtain a more stable and more reliable structure, to achieve better functions and performances.

In order to achieve the above object, one embodiment of the present disclosure provides a semiconductor device including a substrate and a capacitor structure. The capacitor structure is disposed on the substrate and includes a plurality of capacitors arranged in an array, wherein at least two of the capacitors physically contact with each other in a horizontal direction horizontal to the substrate.

In order to achieve the above object, another embodiment of the present disclosure provides a semiconductor device including a semiconductor device including a substrate, a capacitor structure, and a supporting structure. The capacitor structure is disposed on the substrate and includes at least one first capacitor and at least one second capacitor. A bottommost surface of a bottom electrode layer of the at least one first capacitor is lower than a bottommost surface of a bottom electrode layer of the at least one second capacitor, and at least one of the at least one first capacitor and the at least one second capacitor includes a bending end. The supporting structure is disposed on the substrate and between the capacitors, the supporting structure includes a first supporting layer and a second supporting layer stacked sequentially from bottom to top.

Overall speaking, according to the semiconductor device of the present disclosure, dummy capacitors are arranged around the storage cell array, whose top electrode layers are in physical contact with each other, capacitor dielectric layer are in physical contact with each other, and/or top electric layers are in physical contact with each other, to improve the possible structural defects of the semiconductor device caused by continuously increased cell-density. Then, the semiconductor device is allowable to obtain a more reliable structure, to achieve better functions and performances.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 2 are schematic diagrams illustrating a semiconductor device according to a first embodiment of the present disclosure, wherein:

FIG. 1 illustrates a top view of a semiconductor device; and

FIG. 2 illustrates a cross-sectional view of a semiconductor device.

FIG. 3 to FIG. 4 are schematic diagrams illustrating a semiconductor device according to a second embodiment of the present disclosure, wherein:

FIG. 3 illustrates a top view of a semiconductor device; and

FIG. 4 illustrates a cross-sectional view of a semiconductor device.

FIG. 5 is a schematic diagram illustrating a semiconductor device according to a third embodiment of the present disclosure.

FIG. 6 is a schematic diagram illustrating a semiconductor device according to a fourth embodiment of the present disclosure.

FIG. 7 is a schematic diagram illustrating a semiconductor device according to a fifth embodiment of the present disclosure.

FIG. 8 is a schematic diagram illustrating a semiconductor device according to a sixth embodiment of the present disclosure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

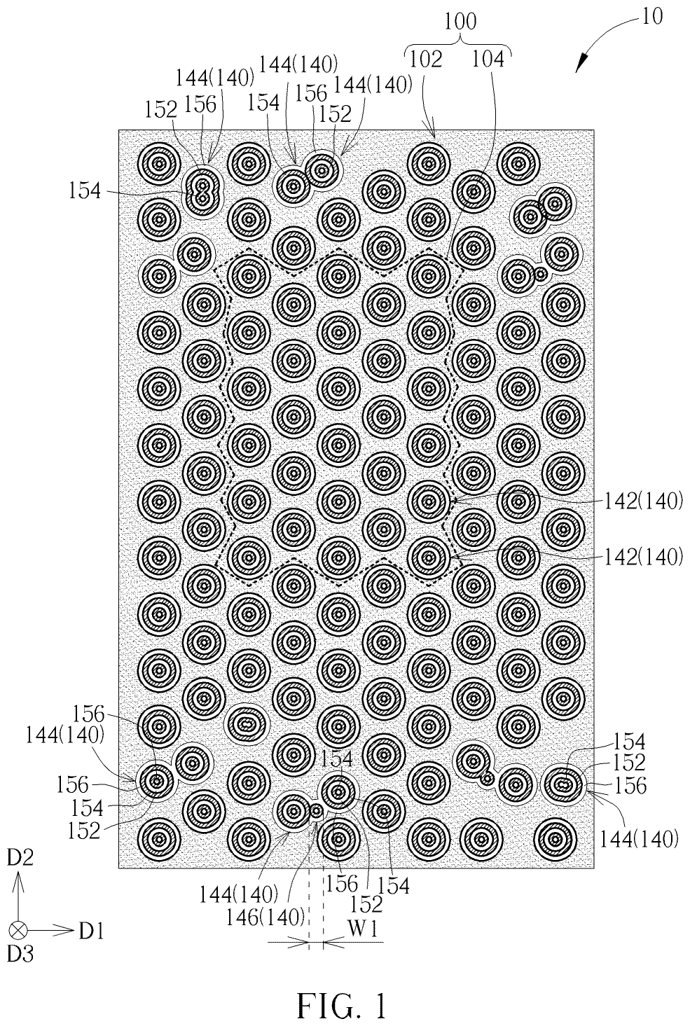

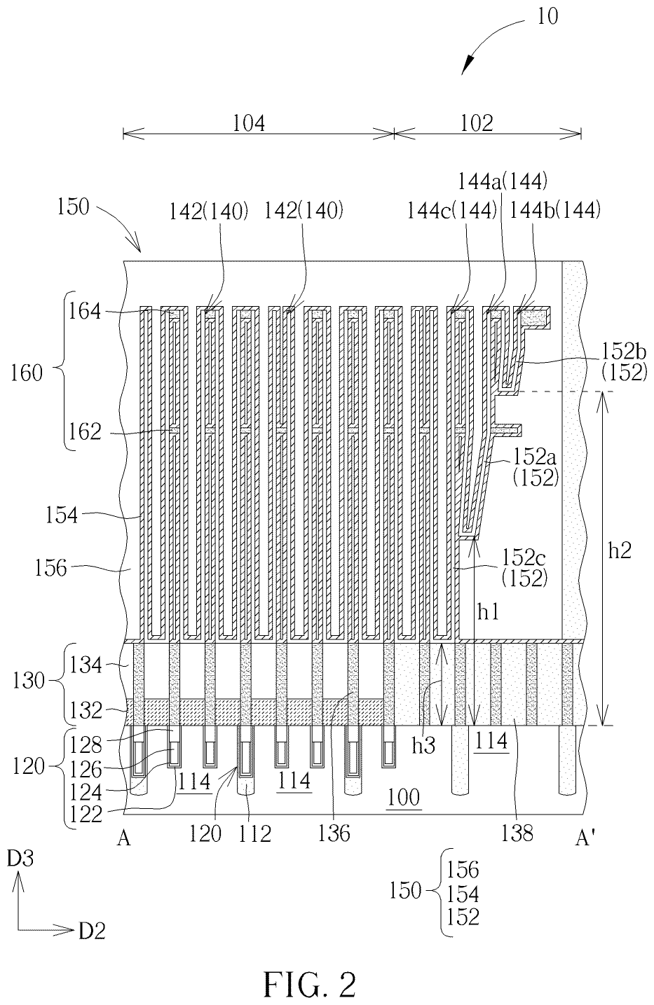

Please refer to FIG. 1 to FIG. 2, which are schematic diagrams illustrating a semiconductor device 10 according to a first embodiment of the present disclosure, with FIG. 1 and FIG. 2 illustrating a top view and a cross-sectional view of the semiconductor device 10 respectively. Firstly, as shown in FIG. 1, the semiconductor device 10 includes a substrate 100 and a capacitor structure 150 disposed on the substrate 100. The substrate 100 for example includes silicon substrate, silicon-containing substrate (for example including SiC or SiGe) or silicon-on-insulator (SOI) substrate. Also, the substrate 100 further includes a region with a relative higher elemental integration, for example being a cell region 104, and another region with a relative lower elemental integration, for example being a peripheral region 102. The cell region 104 and the periphery region 102 may be adjacent to each other, but not limited thereto. preferably, the peripheral region 102 is disposed around at the periphery of the cell region 104, as shown in FIG. 1, but not limited thereto.

The capacitor structure 150 is disposed on the substrate 100, and which includes a plurality of capacitors 140 alternately arranged in a horizontal direction D1 being horizontal to the substrate 100, with the capacitors 140 being arranged along the horizontal direction D1 and a vertical direction D2 into an array. Capacitors 142 disposed within the cell region 104 are separately from each other by a supporting structure 160 disposed therebetween, so that, each capacitor 142 may be electrically connected to a transistor element (not shown in the drawings) within the substrate 100, via a plug (not shown in FIG. 1) underneath, thereby forming a storage cell array. It is noted that, at least two capacitors 144, 146 disposed within the peripheral region 102 physically contact with each other in the horizontal direction D1, to function like a dummy capacitor. Thus, through arranging the dummy capacitors each physically contacting with another at the outer periphery of the storage cell array, the difference of the elemental density between the cell region 104 and the peripheral region 102 will be balanced while fabricating the semiconductor device 10, thereby improving the possible structural defects of the semiconductor device caused by continuously increased cell-density. In this way, the semiconductor device 10 is allowable to obtain a more reliable structure, to achieve better functions and performances.

Precisely speaking, further in view of FIG. 1, the capacitor structure 150 includes a bottom electrode layer 152, a capacitor dielectric layer 154, and a top electrode layer 156 disposed in the horizontal direction D1, with the capacitor dielectric layer 154 being disposed at a side of the bottom electrode layer 152, and with the top electrode layer 156 being further disposed at a side of the capacitor dielectric layer 154, to configure as each capacitor 140. In the present embodiment, the bottom electrode layer 152 for example includes an U-shaped bottom electrode (as shown in FIG. 2) having an U-shaped cross-section structure, and the top electrode layer 156 is filled in the gap between the U-shaped cross-section of the bottom electrode layer 152. In one embodiment, the top electrode layer 156 may optionally include a monolayer structure or a multilayer structure, with the multilayer structure of the top electrode layer 156 being disposed at an inner side and an outer side of the bottom electrode layer 152, as shown in FIG. 1. Accordingly, each capacitor 140 will present in a cylinder cross-sectional structure, but not limited thereto. In another embodiment, two capacitors 144 disposed within the peripheral region 102 physically contact with each other for example through the connecting bottom electrode layers 152, the connecting capacitor dielectric layer 154, or the connecting top electrode layer 156, to function like the dummy capacitor as shown in FIG. 1, but not limited thereto. Alternately, at least one capacitor 146 disposed within the peripheral region 102 includes a relative smaller width W1 in the horizontal direction D1, such that which may directly contact other capacitors 144 adjacent thereto. Through these arrangements, two or more than two capacitors 144, 146 within the peripheral region 102 contacts with each other to function like the dummy capacitors, optionally through the contacting bottom electrode layers 152, the contacting top electrode layers 156, or the capacitor dielectric layers 154.

On the other hands, as shown in the cross-sectional view of FIG. 2, the semiconductor device 10 includes a substrate 100, the capacitor structure 150, and a supporting structure 160 disposed on the substrate 100, between each capacitor 140. The supporting structure 160 precisely includes a first supporting layer 162 and a second supporting layer 164 stacked from bottom to top, for supporting the middle portion and the top portion of each capacitor 140 respectively, but not limited thereto. It is noted that, there is no plug disposed under the capacitors 144 with in the peripheral region 102, so that, the capacitors 144 will not electrically connect to the transistor element in the substrate 100, to function like the dummy capacitors thereby. The bottommost surfaces of the bottom electrode layers 152a, 152b, 152c, of at least two capacitors 144a, 144b, 144c to a top surface of the substrate 100 are in different heights in the vertical direction D3. Precisely, the bottommost surface of the bottom electrode layer 152a of one capacitor 144a is lower than the bottommost surface of the bottom electrode layer 152b of another capacitor 144b, with the bottom electrode layer 152a of the capacitor 144a and/or the bottom electrode layer 152b of the capacitor 144b includes a bending end at the bottom thereof, but not limited thereto. In another embodiment, the bottommost surface of the bottom electrode layer 152c of one capacitor 144c is lower than the bottommost surfaces of the bottom electrode layers 152a, 152b of the capacitors 144a, 144b, with the bottom electrode layer 152a of the capacitor 144a and/or the bottom electrode layer 152b of the capacitor 144b includes a bending end at the bottom thereof. Through these arrangements, the difference of the elemental density between the cell region 104 and the peripheral region 102 will also be balanced while fabricating the semiconductor device 10, so as to improve the possible structural defects of the semiconductor device caused by continuously increased cell-density. Then, the semiconductor device 10 of the present embodiment enables to obtain a more reliable structure, to achieve better functions and performances.

Precisely speaking, further in view of FIG. 2, the capacitor structure 150 includes the bottom electrode layer 152, the capacitor dielectric layer 154, and the top electrode layer 156 stacked in sequence in the vertical direction D3. In the present embodiment, the bottom electrode layer 152 for example includes a continuously extended U-shaped cross-section, the capacitor dielectric layer 154 is disposed on the sidewalls and the bottom surface of the U-shaped cross-section of the bottom electrode layer 152, and the top electrode layer 156 is filled in the gap of the U-shaped cross-section of the bottom electrode layer 152. Accordingly, each capacitor 144 disposed within the peripheral region 102 will substantially include a cylinder cross-sectional structure, but not limited thereto. It is noted that, the bending ends of the bottom electrode layers 152a, 152b of the capacitors 144a, 144b are for example disposed between the top surface of the substrate 100 and the first supporting layer 162, or between the first supporting layer 162 and the second supporting layer 164, with each bending end gradually bent toward another capacitor 144c adjacent thereto. In one embodiment, the bending ends of the bottom electrode layers 152b, 152a, 152c are preferably not in physical contact with the bottom electrode layers 152b, 152a, 152c of the capacitors 144b, 144a, 144c being adjacent thereto, and the capacitor dielectric layer 154 covering on the aforementioned bending ends is in physical contact with the capacitor dielectric 154 covering on the bottom electrode layers 152b, 152a, 152c of the capacitors 144b, 144a, 144c being adjacent thereto, a shown in FIG. 2, but not limited thereto.

The semiconductor device 10 further includes a plurality of buried gate structure 120 disposed within the substrate, and a plurality of plugs 130 disposed on the substrate 100, both within the cell region 104. Precisely speaking, the gate structures 120 are extended along a direction (not shown in the drawings) in the substrate, to intersect a shallow trench isolation 112 and a plurality of active areas 114 in the substrate 100. Each of the gate structures 120 further includes a dielectric layer 122, a gate dielectric layer 124, a gate layer 126, and a capping layer 128 stacked in sequence, with a surface of the capping layer 128 being coplanar with a top surface of the substrate 100, so that, the gate structures 120 may therefore function like buried word lines (BWLs) of the semiconductor device 10. Each of the plugs 130 further includes a storage node contact 132 and a storage node pad 134 disposed on the substrate 100, and two adjacent ones of the plugs 130 are isolated from each other through a storage node contact isolation (SCISO) 136 right above each gate structure 120. In one embodiment, the storage node contact 132 for example includes an epitaxial material like silicon, silicon phosphate (SiP), silicon germanium (SiGe), or germanium, the storage node pad 134 for example includes a low-resistance metal material like aluminum (Al), titanium (Ti), copper (Cu), or tungsten (W), but not limited thereto. In another embodiment, the storage node pad 134 may optionally include the same conductive material as that of the storage node contact 132, but is not limited thereto.

Through these arrangements, each capacitor 142 disposed within the cell region 104 enables to electrically connect to the transistor element within the substrate 100 through the plug 130 disposed underneath, and the capacitors 142 and the plugs 130 will together serve as a smallest memory cell of a storage cell array in a dynamic random access memory (DRAM, not shown in the drawings), for receiving voltage signals from bit line (BL, not shown in the drawings) and the word lines (namely, the gate structures 120). On the other hand, each capacitor 144 disposed within the peripheral region 102 only contacts the insulating layer 138 underneath, and which cannot electrically connect to the transistor element within the substrate 100, thereby serving as a dummy capacitor. It is noted that although the bit lines are not illustrated in the drawings of the present disclosure, those who skilled in the arts should fully realize the bit lines are parallel with each other in a direction being perpendicular to the word lines (namely, the gate structures 120), with a bit line contact (BLC) disposed underneath to electrically connect to the substrate 100, and with an insulating layer (for example including an oxide-nitride-oxide structure, not shown in the drawings) disposed on the substrate 100 to electrically isolating the gate structures 120 within the substrate.

According to the semiconductor device 10 of the first embodiment, the capacitors within the peripheral region 102 are physically in contact with each other through the connecting bottom electrodes 152, the connecting capacitor dielectric layers 154, and/or the connecting top electrode layers 156, so as to configure as the dummy capacitors thereby. Then, the difference of the elemental density between the cell region 104 and the peripheral region 102 will be balanced through arranging the dummy capacitors, so as to improve the possible structural defects of the semiconductor device 10 caused by continuously increased cell-density. In this way, the semiconductor device 10 is allowable to obtain a more reliable structure, to achieve better functions and performances.

Those of ordinary skill in the art should easily realize the semiconductor device in the present disclosure is not limited to the aforementioned embodiment, and which may include other examples or varieties. The following description will detail the different embodiments of the semiconductor device in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

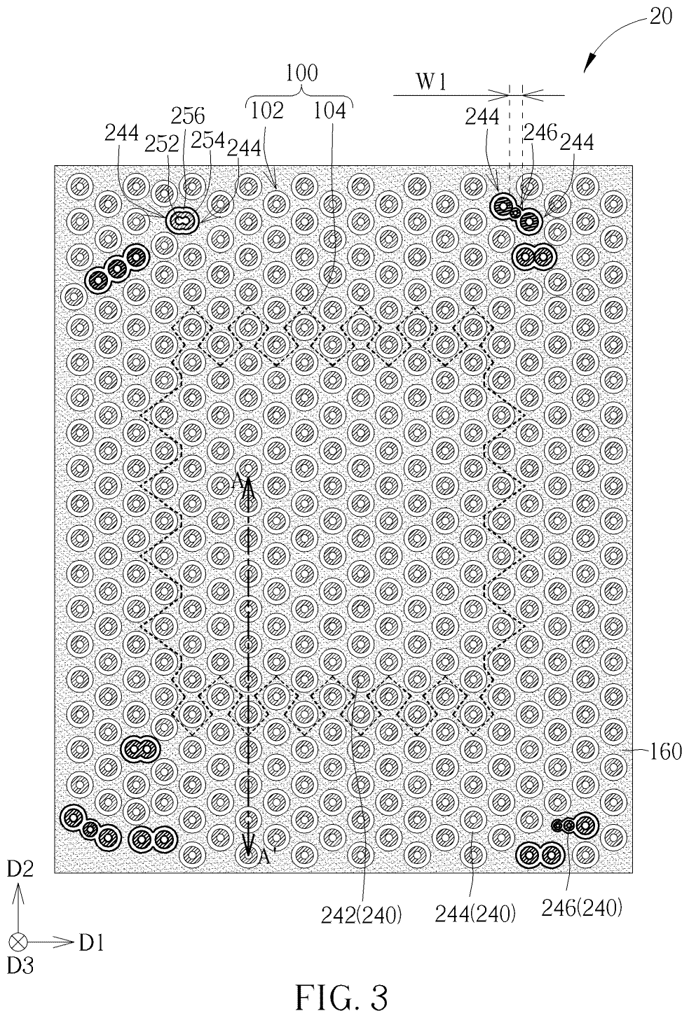

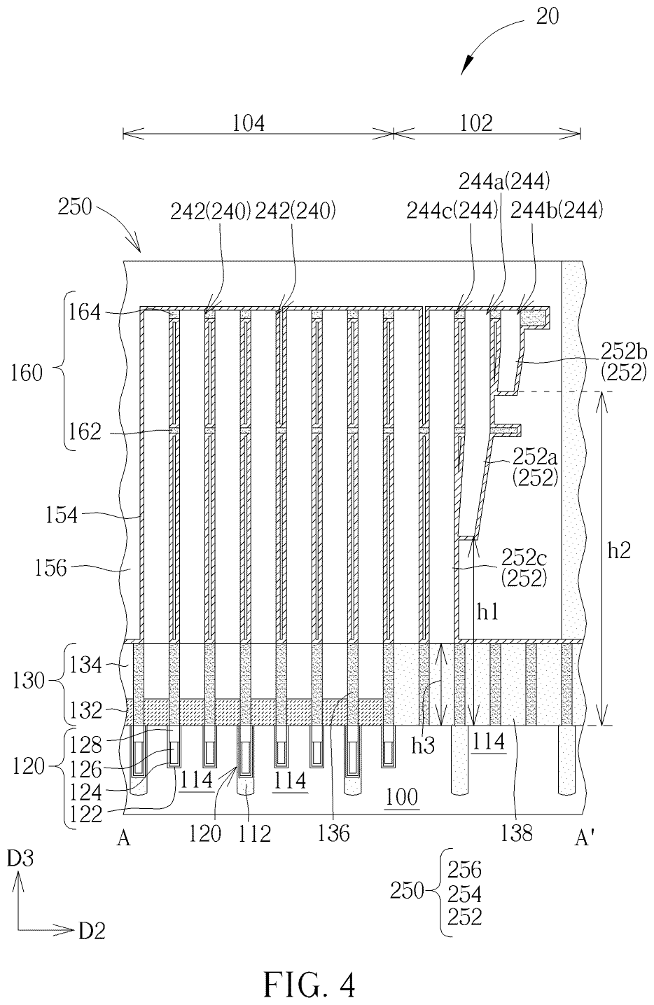

Please refer to FIG. 3 and FIG. 4, which are schematic diagrams illustrating a semiconductor device 20 according to the second embodiment of the present disclosure, with FIG. 3 and FIG. 4 illustrating a top view and a cross-sectional view of the semiconductor device 20 respectively. The difference between the semiconductor device 20 of the present embodiment and the semiconductor device 10 of the aforementioned embodiment is mainly in that the capacitor structure 250 includes a bottom electrode layer 252, a capacitor dielectric layer 254, and a top electrode layer 256 stacked in sequence in the horizontal direction D1, to form a plurality of capacitors 240, with each capacitor 240 having a cylinder cross-section, but not limited thereto. The bottom electrode layer 252 for example includes a columnar bottom electrode, and the capacitor dielectric layer 254 and the top electrode layer 256 cover the outer side of the bottom electrode layer 252 in sequence, surrounding the columnar bottom electrode thereby.

The capacitors 240 are arranged in the horizontal direction D1 and the vertical direction D2 into an array, with the supporting structure 160 being disposed between the capacitors 242 within the cell region 104 for isolating and supporting thereto. Each of the capacitors 242 may be electrically connected to the transistor element within the substrate 100 through the plug 130 underneath (as shown in FIG. 4), to form the storage cell array. It is noted that, at least two capacitors 244, 246 disposed within the peripheral region 102 physically contact with each other in the horizontal direction D1, to function like a dummy capacitor. In one embodiment, two capacitors 244 within the peripheral region 102 are physically in contact with each other through the connecting bottom electrodes 252, the connecting capacitor dielectric layers 254, and/or the connecting top electrode layers 256, to configured as the dummy capacitors as shown in FIG. 3, but not limited thereto. Alternately, at least one capacitor 246 within the peripheral region 102 includes a relative smaller width W1 in the horizontal direction D1, and which enables to directly contact other capacitors 244 adjacent thereto. Through these arrangements, two or more than two capacitors 244, 246 within the peripheral region 102 contact with each other through the connecting top electrode layers 256, the connecting capacitor dielectric layer 254, or the connecting bottom electrode layers 252, to form the dummy capacitors.

On the other hand, as shown in FIG. 4, the bottommost surfaces of the bottom electrode layers of at least two capacitors 244a, 244b, 244c to a top surface of the substrate 100 are in different heights h1, h2, h3 in the vertical direction D3. Precisely, the bottommost surface of the bottom electrode layer 252a of the capacitor 244a is lower than the bottommost surface of the bottom electrode layer 252b of another capacitor 244b, with the bottom electrode layer 252a of the capacitor 244a and/or the bottom electrode layer 252b of the capacitor 244b including a bending end at the bottom thereof, but not limited thereto. Alternately, the bottommost surface of the bottom electrode layer 252c of the capacitor 244c is lower than the bottommost surface of the bottom electrode layer 252a, 252b of the capacitors 244a, 244c, with the bottom electrode layer 252a of the capacitor 244a and/or the bottom electrode layer 252b of the capacitor 244b including a bending end at the bottom thereof.

According to the semiconductor device 20 of the present embodiment, the capacitors 242 within the peripheral region 102 still physically contact with each other through the connecting bottom electrode layers 252, the connecting capacitor dielectric layer 254, and/or the connecting top electrode layers 256, to serve as the dummy capacitors. With these arrangements, the difference of the elemental density between the cell region 104 and the peripheral region 102 will be balanced through arranging the dummy capacitors, so as to improve the possible structural defects of the semiconductor device 20 caused by continuously increased cell-density. In this way, the semiconductor device 20 is allowable to obtain a more reliable structure, to achieve better functions and performances.

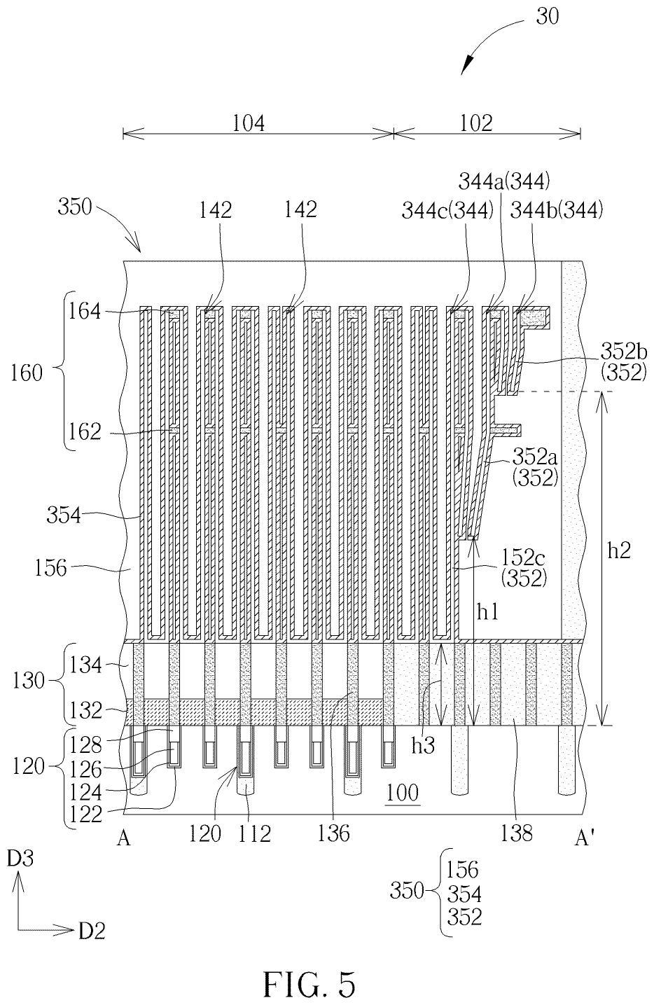

Please refer to FIG. 5, which is a schematic diagram illustrating a semiconductor device 30 according to the third embodiment of the present disclosure. The structure of the semiconductor device 30 is substantially the same as that of the semiconductor device 10 of the aforementioned first embodiment, with all the similarities being not redundantly described hereinafter. The difference between the semiconductor device 30 of the present embodiment and the semiconductor device 10 of the aforementioned first embodiment is mainly in that the capacitor structure 350 includes a bottom electrode layer 352, a capacitor dielectric layer 354, and a top electrode layer 156 stacked in sequence, to form a plurality of capacitors 142, 344 within the cell region 104 and the peripheral region 102. It is noted that the bottom electrode layer 352a, 352b of at least one of the capacitors 344a, 344b within the peripheral region 102 includes a discontinuously film at the bottom thereof.

Precisely speaking, the bottom electrode layer 352a of the capacitor 344a and the bottom electrode layer 352b of the capacitor 344b each includes two portions that gradually bending toward an adjacent capacitor 144c, 344b at the same side, such that, the bottoms of the two portions are not connected with each other. Then, the bottom electrode layers 352a and 352b of the capacitors 344a and 344b are respectively in a discontinuous structure, as shown in FIG. 5. Furthermore, the subsequent capacitor dielectric layer 354 covering on the two portions are also not connected with each other, to present in a discontinuous structure as shown in FIG. 5, but not limited thereto. However, in another embodiment, the capacitor dielectric layer 354 covering on the two portions may physically contact the capacitor dielectric layer 354 covering on the bottom electrode layer 352, 352a, 152 of an adjacent capacitor 344, optionally. According to the semiconductor device 30 of the present embodiment, the capacitors 342 within the peripheral region 102 still physically contact with each other through the connecting bottom electrode layers 352, the connecting capacitor dielectric layer 354, and/or the connecting top electrode layers 156, to serve as the dummy capacitors. With these arrangements, the difference of the elemental density between the cell region 104 and the peripheral region 102 will be balanced through arranging the dummy capacitors, so as to improve the possible structural defects of the semiconductor device 30 caused by continuously increased cell-density. In this way, the semiconductor device 30 of the present embodiment is allowable to obtain a more reliable structure, to achieve better functions and performances.

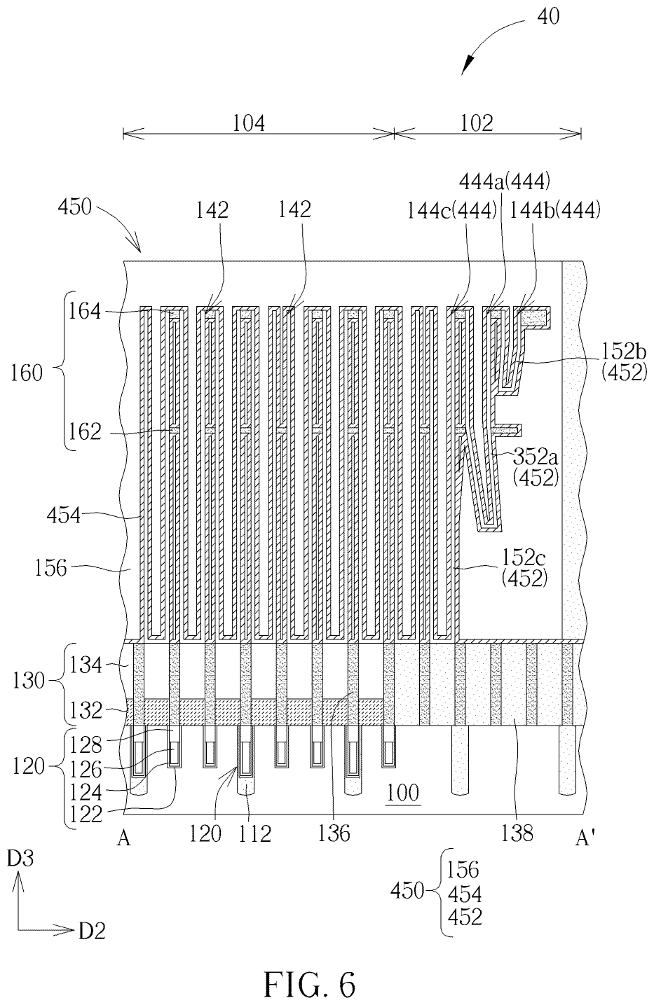

Please refer to FIG. 6, which is a schematic diagram illustrating a semiconductor device 40 according to the fourth embodiment of the present disclosure. The structure of the semiconductor device 40 is substantially the same as that of the semiconductor device 10 of the aforementioned first embodiment, with all the similarities therebetween being not redundantly described hereinafter. The difference between the semiconductor device 40 of the present embodiment and the semiconductor device 10 of the aforementioned first embodiment is mainly in that the capacitor structure 450 includes a bottom electrode layer 452, a capacitor dielectric layer 454, and a top electrode layer 156 stacked in sequence, to form a plurality of capacitors 142, 444 within the cell region 104 and the peripheral region 102. It is noted that the bottom electrode layer 452a of at least one capacitor 444a with in the peripheral region 102 includes a bending end at the bottom thereof, being gradually bent toward another capacitor 144b.

Precisely speaking, the bottom electrode layer 452s of the capacitor 444a includes the bending end that gradually bends toward the adjacent capacitor 144b at one side, while the bottom electrode layer 152b of the capacitor 144b also includes a bending end that gradually bends toward the capacitor 444a. That is, the bending ends of the bottom electrode layer 452a of the capacitor 444a and the bottom electrode layer 152b of the capacitor 144b are opposite to each other and gradually approach to each other. The bending end of the bottom electrode layer 452a of the capacitor 444a is located between the surface of the substrate 100 and the first support layer 162, while the bending end of the bottom electrode layer 152b of the capacitor 144b is located between the first support layer 162 and the second support layer 164, as shown in FIG. 6. Also, since the bending ends of the bottom electrode layers 152b of the capacitor 444a and the capacitor 144b gradually approach each other, the capacitor dielectric layers 454 covering on the bottom electrode layer 452a of the capacitor 444a and the bottom electrode layer 152b of the capacitor 144b are in directly contact with each thereto, but not limited thereto. However, in another embodiment, the bottom electrode layers of the capacitor 444a and the capacitor 144b may also be in directly contact (not shown in the drawing), optionally. According to the semiconductor device 40 of the present embodiment, the capacitors 442 within the peripheral region 102 still physically contact with each other through the connecting bottom electrode layers 452, the connecting capacitor dielectric layer 454, and/or the connecting top electrode layers 156, to serve as the dummy capacitors. With these arrangements, the difference of the elemental density between the cell region 104 and the peripheral region 102 will be balanced through arranging the dummy capacitors, so as to improve the possible structural defects of the semiconductor device 40 caused by continuously increased cell-density. In this way, the semiconductor device 40 is allowable to obtain a more reliable structure, to achieve better functions and performances.

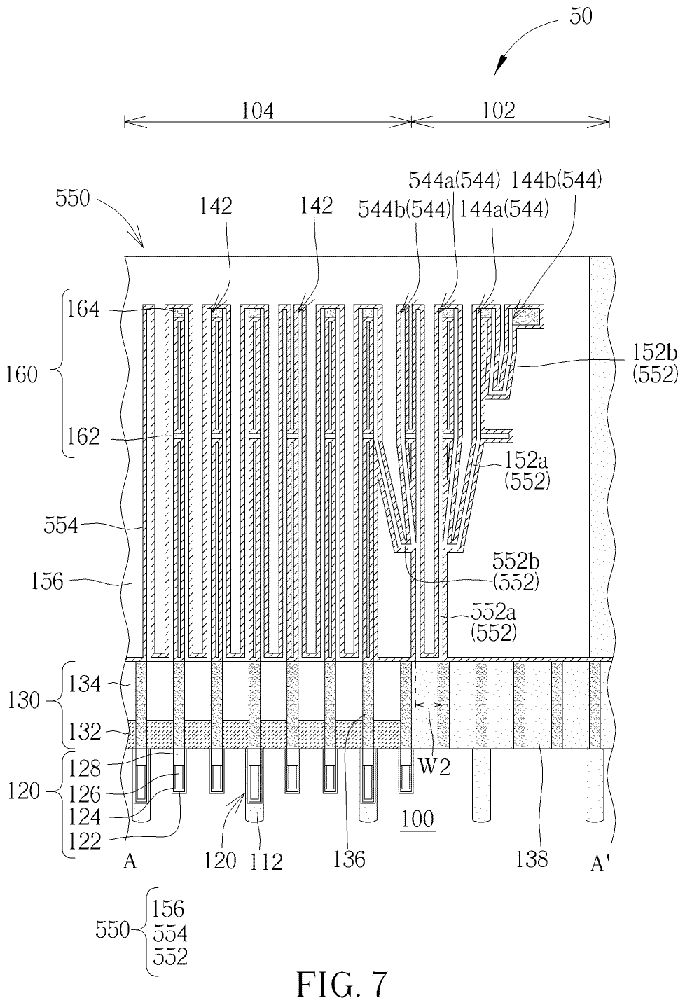

Please refer to FIG. 7, which is a schematic diagram illustrating a semiconductor device 50 according to the fifth embodiment of the present disclosure. The structure of the semiconductor device 50 is substantially the same as that of the semiconductor device 10 of the aforementioned first embodiment, with all the similarities being not redundantly described hereinafter. The difference between the semiconductor device 50 of the present embodiment and the semiconductor device 10 of the aforementioned first embodiment is mainly in that the capacitor structure 550 includes a bottom electrode layer 552, a capacitor dielectric layer 554, and a top electrode layer 156 stacked in sequence, to form a plurality of capacitors 142, 544 within the cell region 104 and the peripheral region 102. It is noted that, the bottom electrode layer 152a of at least one capacitor 144a within the peripheral region 102 includes a bending end at the bottom thereof, being gradually bent toward another capacitor 544a at the bottom thereof.

Precisely speaking, the capacitor 544a extends in the vertical direction D3 and is disposed on the substrate 100, with the bottom electrode layer 522a includes a continuously extending U-shaped cross-section. The bottom electrode layer 152a of the capacitor 144a and the bottom electrode layer 552b of the capacitor 544b each includes a bending end gradually bent toward the capacitor 544a, so that, the vertically extended capacitor 544a is sandwiched between the capacitor 144a and the capacitor 544b with the bending end. In addition, since the bottom electrode layer 552a of the capacitor 544a has a relatively small width W2 than that of other capacitors 544, the bending ends of the bottom electrode layer 152a of the capacitor 144a and the bottom electrode layer 522b of the capacitor 544b gradually approach and physically contact the bottom electrode layer 552a of the capacitor 544a, with the bottom electrode layer 552a of the capacitor 544a being sandwiched therebetween, as shown in FIG. 7. However, in another embodiment, the bending ends of the bottom electrode layer 152a of the capacitor 144a and the bottom electrode layer 552b of the capacitor 544b may also gradually approach to and not in physically contact with the bottom electrode layer 552a of the capacitor 544a, so that, the capacitor dielectric layer covering on the bottom electrode layer 152a of the capacitor 144a, the bottom electrode layer 552b of the capacitor 444b, and the bottom electrode layer 552a of the capacitor 444a will be connected and contacted with each other, but not limited thereto. According to semiconductor device 50 of the present embodiment, the capacitors 542 within the peripheral region 102 still physically contact with each other through the connecting bottom electrode layers 552, the connecting capacitor dielectric layer 554, and/or the connecting top electrode layers 156, to serve as the dummy capacitors. With these arrangements, the difference of the elemental density between the cell region 104 and the peripheral region 102 will be balanced through arranging the dummy capacitors, so as to improve the possible structural defects of the semiconductor device 50 caused by continuously increased cell-density. In this way, the semiconductor device 50 is allowable to obtain a more reliable structure, to achieve better functions and performances.

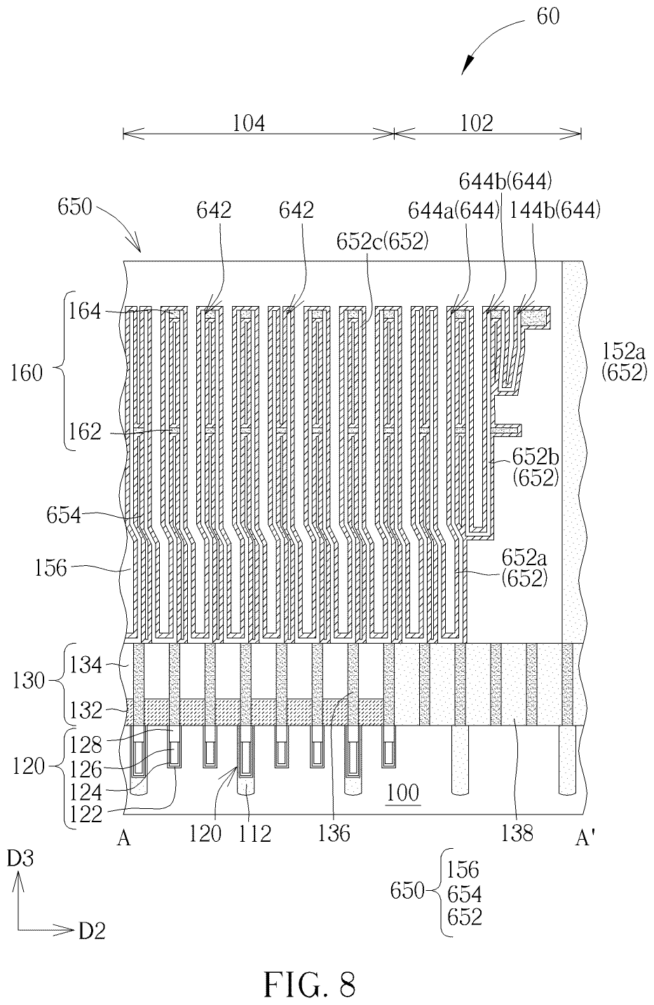

Please refer to FIG. 8, which is a schematic diagram illustrating a semiconductor device 60 according to the sixth embodiment of the present disclosure. The structure of the semiconductor device 60 is substantially the same as that of the semiconductor device 10 of the aforementioned first embodiment, with all the similarities therebetween being not redundantly described hereinafter. The difference between the semiconductor device 60 of the present embodiment and the semiconductor device 10 of the aforementioned first embodiment is mainly in that the capacitor structure 650 includes a bottom electrode layer 652, a capacitor dielectric layer 654, and a top electrode layer 156 stacked in sequence, to form a plurality of capacitors 642, 644 within the cell region 104 and the peripheral region 102. It is noted that the bottom electrode layer 652a of at least one capacitor 644a within the peripheral area 102 includes a bending end that gradually bending towards another capacitor 644b, while the bottom electrode layer 652c of at least one capacitor 644c within the cell region 104 also includes a bending end that gradually bends towards the capacitor 644b, with the bottoms of the bottom electrode layers 652a, 652c still in physical contact with the insulating layer 138 or the plug 130 underneath.

Precisely speaking, the capacitors 642, 644a respectively arranged in the cell region 104 and the peripheral region 102 extend in the vertical direction D3, over the substrate 100. The bending ends of the bottom electrode layers 652c and 652a of the capacitors 642 and 644a are located between the surface of the substrate 100 and the first support layer 162, to substantially present in a continuously extending U-shaped cross section, as shown in FIG. 8. The bending end of the bottom electrode layer 652a of the capacitor 644a is preferably approach to and not in physically contact with the bottom electrode layer 652b of the adjacent capacitor 644b, so that, the capacitor dielectric layers 654 covering the bottom electrode layers 652a, 652b of the capacitors 644a and 644b are connected and contacted with each other, but not limited thereto. However, in another embodiment, the bottom electrode layers 652a, 652b of the capacitors 644a, 644b may also be in direct contact with each other. Then, the capacitor 642 arranged in the cell region 104 will still be aligned with a corresponding plug underneath, to form a storage cell array, while the capacitors 644a, 644b and 144b arranged in the peripheral region 102 contact the insulating layer 138 to serve as the dummy capacitors.

According to the semiconductor device 60 of the present embodiment, the capacitors 642 within the peripheral region 102 still physically contact with each other through the connecting bottom electrode layers 652, the connecting capacitor dielectric layer 654, and/or the connecting top electrode layers 156, to serve as the dummy capacitors. With these arrangements, the difference of the elemental density between the cell region 104 and the peripheral region 102 will be balanced through arranging the dummy capacitors, so as to improve the possible structural defects of the semiconductor device 60 caused by continuously increased cell-density. In this way, the semiconductor device 60 is allowable to obtain a more reliable structure, to achieve better functions and performances. In addition, those skilled in art should fully realize that although the semiconductor device 60 of the present embodiment includes the capacitors 644a, 644b, 144b within the peripheral region 102 serving as the dummy capacitors, the practical structure of the dummy capacitors is not limited to which is shown in FIG. 8, and which may also include the capacitors 544a, 544b as shown in FIG. 7 to serve as the dummy capacitors, the capacitor 444a as shown in FIG. 6 to serve as the dummy capacitors, or the capacitor 344a, 344, 344c as shown in FIG. 5 to serve as the dummy capacitors, due to the specific product requirements. The bottom electrode layers of the aforementioned capacitors may optionally contact or not contact the bottom electrode layer 652c of an adjacent capacitor 642, to obtain a more reliable structure thereby.

Overall speaking, according to the semiconductor device of the present disclosure, dummy capacitors are arranged around the storage cell array, whose top electrode layers are in physical contact with each other, capacitor dielectric layer are in physical contact with each other, and/or top electric layers are in physical contact with each other, optionally to improve the possible structural defects of the semiconductor device caused by continuously increased cell-density. Then, the semiconductor device of the present disclosure is allowable to obtain a more reliable structure, to achieve better functions and performances.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate; and
a capacitor structure, disposed on the substrate and comprising a plurality of capacitors arranged in an array,
wherein at least two of the capacitors physically contact with each other in a horizontal direction being horizontal to the substrate.

2. The semiconductor device according to claim 1, wherein each of the capacitors comprises a bottom electrode layer, a capacitor dielectric layer and a top electrode layer disposed in sequence along the horizontal direction.

3. The semiconductor device according to claim 2, wherein the bottom electrode layers of at least two of the capacitors physically contact with each other.

4. The semiconductor device according to claim 2, wherein the top electrode layers of at least two of the capacitors physically contact with each other.

5. The semiconductor device according to claim 2, wherein the capacitor dielectric layers of at least two of the capacitors physically contact with each other.

6. The semiconductor device according to claim 1, wherein at least two of the capacitors are in different widths in the horizontal direction.

7. A semiconductor device, comprising:
a substrate; and
a capacitor structure, disposed on the substrate and comprising at least one first capacitor and at least one second capacitor, a bottommost surface of a bottom electrode layer of the at least one first capacitor is lower than a bottommost surface of a bottom electrode layer of the at least one second capacitor, and at least one of the at least one first capacitor and the at least one second capacitor comprises a bending end; and
a supporting structure, disposed on the substrate and between the at least one first capacitor and the at least one second capacitor, the supporting structure comprising a first supporting layer and a second supporting layer stacked in sequence from bottom to top.

8. The semiconductor device according to claim 7, wherein the bottom electrode layer of the at least one first capacitor bends toward one side of the at least one second capacitor.

9. The semiconductor device according to claim 7, wherein the bottom electrode layer of the at least one second capacitor bends toward one side of the at least one first capacitor.

10. The semiconductor device according to claim 7, wherein a bottommost surface of the bending end of the bottom electrode layer of the at least one second capacitor is disposed between the first supporting layer and the second supporting layer.

11. The semiconductor device according to claim 7, wherein a bottommost surface of the bending end of the bottom electrode layer of the at least one second capacitor is disposed between the first supporting layer and the substrate.

12. The semiconductor device according to claim 7, wherein the bottom electrode layer of the at least one second capacitor comprises a discontinuous bottom structure.

13. The semiconductor device according to claim 7, wherein the at least one first capacitor and the at least one second capacitor comprise a cylinder cross-sectional structure respectively.

14. The semiconductor device according to claim 7, wherein the bending end of the bottom electrode layer of the at least one second capacitor does not physically contact the bottom electrode layer of the at least one first capacitor.

15. The semiconductor device according to claim 14, wherein a capacitor dielectric layer disposed on the bottom electrode layer of the at least one first capacitor physically contacts a capacitor dielectric layer disposed on the bottom electrode layer of the at least one second capacitor.

16. The semiconductor device according to claim 14, wherein a capacitor dielectric layer disposed on the bottom electrode layer of the at least one first capacitor does not physically contact a capacitor dielectric layer disposed on the bottom electrode layer of the at least one second capacitor.

17. The semiconductor device according to claim 7, wherein the bottom electrode layer of the at least one first capacitor physically contacts the bottom electrode layer of the at least one second capacitor.

18. The semiconductor device according to claim 7, wherein a width of the bottom electrode layer of the at least one first capacitor is different from a width of the bottom electrode layer of the at least one second capacitor.

19. The semiconductor device according to claim 7, wherein the bottom electrode layer of the at least one first capacitor comprises the bending end, and the bottom electrode layer of the at least one second capacitor is vertically disposed on the substrate.
